(19) United States
(12) Patent Application Publication
(10) Pub. No.: US 2005/0188922 A1
(43) Pub. Date: Sep. 1, 2005

(54) Plasma processing unit

(75) Inventors: Kiyotaka Ishibashi, Amagasaki-shi (JP); Cai zhong Tian, Amagasaki-city (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: TOKYO ELECTRON LIMITED.

(21) Appl. No.: 11/064,012

(22) Filed: Feb. 24, 2005

(30) Foreign Application Priority Data
Feb. 26, 2004 (JP) JP2004-050993

(51) Int. Cl. C23C 16/00

(52) U.S. Cl. 118/723 I

(57) ABSTRACT

According to the present invention, since the inside of a hole formed in a sidewall of a process vessel of a plasma processing unit is filled with a dielectric, a propagation rate of the electromagnetic wave to a pickup antenna is improved when an electromagnetic wave generated due to abnormality in plasma such as abnormal discharge is to be detected via the hole. Accordingly, it is possible to improve detection sensitivity without any change in size or length of the hole. Consequently, abnormal discharge in plasma processing can be detected with high accuracy.

### BACKGROUND OF THE INVENTION

1. Field of the Invention

The present invention relates to a plasma processing unit.

2. Description of the Related Art

Conventionally, a plasma processing unit has been proposed that generates plasma in a process vessel through the use of a microwave or other high-frequency wave to apply various kinds of plasma processing such as, for example, CVD processing or etching processing to a substrate placed in the process vessel.

In the plasma processing, abnormal discharge, if occurring in the plasma generated in the process vessel, may possibly impair uniformity of plasma density and result in inappropriate plasma processing itself. Therefore, a system including a detector, which is provided outside a process vessel, for monitoring the condition of plasma has been conventionally been proposed (Japanese Patent Application Laid-open No. Hei 9-266098). When abnormal discharge occurs in the process vessel, this detector detects an electromagnetic wave with a specific frequency that is generated due to the abnormal discharge different from plasma discharge, to thereby judge the existence of an abnormal plasma condition.

Such a detector includes an antenna or the like for picking up an electromagnetic wave generated due to the abnormal discharge, but the detector itself cannot be installed in the process vessel. Therefore, a conventional plasma processing unit is structured such that a through hole called a port is formed in a wall, for example, a sidewall of the process vessel, an outer side (for example, an atmosphere side) of this through hole is airtightly covered with a window member made of a dielectric or the like, and the detector is installed outside the window member (Japanese Patent Application Laid-open No. Hei 10-168568). The pickup antenna of the detector receives the electromagnetic wave propagating through the through hole to send a signal of the electromagnetic wave to a predetermined circuit or the like.

Incidentally, the through hole is designed to have a cross section as small as possible in consideration of the influence that it might give to the processing. However, such a through hole functions as a kind of a waveguide for a high-frequency wave, and there may be a case where a signal with a frequency lower than a cutoff frequency (a lower limit frequency at which an electric field propagation rate becomes 1) does not sufficiently reach the pickup antenna.

For example, if a through hole is formed to have a diameter of about 10 mm and a length of about 30 mm, as in a through hole often used as a detection port of this kind, the cutoff frequency in the lowest order TE₁₁ mode becomes as high as 8.8 GHz. This limits a signal detector to be used and necessitates an expensive measurement instrument. Moreover, a lower limit of a band of a high-frequency wave generated due to an abnormal discharge phenomenon such as an arc and a spark is relatively low, for example, several kHz, and therefore, in order to detect minute abnormal discharge, it is preferable that a frequency in up to a lower band can be detected.

Reduction in length of the through hole, in other words, reduction in thickness of the wall of the process vessel would result in an improved propagation rate, but pose a problem in terms of strength of the process vessel itself. The plasma processing of this kind is performed under a reduced pressure approximate to a vacuum degree, and therefore, in view of its strength, there is a limit to reducing the thickness of the wall constituting the process vessel.

### SUMMARY OF THE INVENTION

The present invention was made in view of the above, and it is an object of the present invention to improve a propagation rate to a pickup antenna of a detector in detecting abnormality in plasma such as abnormal discharge in a process vessel via a through hole, without reducing the thickness of a wall of the process vessel.

In order to achieve the above object, a plasma processing unit (a plasma processing apparatus) of the present invention includes: a dielectric at least partly facing a space in the process vessel of the plasma processing unit; and a detector having a pickup antenna that receives, via the dielectric, an electromagnetic wave generated due to abnormality in plasma in the process vessel.

The plasma processing unit may further include: a hole passing through a wall of the process vessel; and a window member airtightly covering an outer side of the hole, and an inside of the hole may be filled with the dielectric.

A hole in a prior art is left hollow, and its inner part has an atmosphere whose pressure reduction degree is the same as that in the process vessel, namely, a substantially vacuum atmosphere. Therefore, receiving the electromagnetic wave via the dielectric or filling the hole with the dielectric can improve a propagation rate of an electromagnetic wave, which is generated due to abnormality in plasma such as abnormal discharge, to a pickup antenna. A cutoff frequency in this case becomes lower in inverse proportion to a square root of a dielectric constant. Therefore, a relative dielectric constant of the filled dielectric (dielectric constant of the dielectric/dielectric constant of a vacuum) is preferably as high as possible, and a dielectric such as, for example, a quartz material with a relative dielectric constant of about 3.7 or higher is highly practical.

According to another aspect of the present invention, the present invention is a plasma processing unit applying plasma processing to a substrate in a process vessel, including: a hole passing through a wall of the process vessel; a window member airtightly covering an outer side of the hole; and a detector having a pickup antenna that receives, via the hole, an electromagnetic wave generated due to abnormality in plasma, wherein the pickup antenna is disposed inside the hole, being covered with a covering member made of a dielectric, and a gap exists between an outer peripheral face of the covering member and an inner peripheral face of the hole.

In such a structure that the pickup antenna covered with the covering member made of the dielectric is disposed inside the hole, the hole need not be completely filled with the dielectric and thus a gap may exist between the covering member and the inner face of the hole. Such arrangement that the pickup antenna covered with the covering member is inserted in the hole allows the pickup antenna to receive the electromagnetic wave at a position closer to the location of the occurrence of abnormality in plasma such as abnormal discharge than in the prior art. This improves a propagation rate to the pickup antenna, resulting in enhanced sensitivity.

According to the present invention, it is possible to improve sensitivity of a pickup antenna and to make a frequency band of a cutoff frequency lower than that in a prior art, without any reduction in thickness of a wall of a process vessel or without any increase in size of a hole itself. Consequently, abnormal discharge and an abnormal plasma condition in the process vessel can be detected with higher accuracy than in the prior art.

### BRIEF DESCRIPTION OF THE DRAWINGS

FIG. 1 is a vertical cross-sectional view of a plasma processing unit according to an embodiment;

FIG. 2 is a vertical cross-sectional view of the vicinity of a hole of a sidewall of the plasma processing unit in FIG. 1;

FIG. 3 is a graph showing the correlation between frequency and propagation rate;

FIG. 4 is a vertical cross-sectional view of the vicinity of the hole in an example where a pickup antenna is disposed in the hole;

FIG. 5 is a vertical cross-sectional view of the vicinity of the hole in an example where an electromagnetic wave propagating member is disposed in the hole;

FIG. 6 is a vertical cross-sectional view of the vicinity of the hole in an example where the outer diameter of an insertion portion is smaller than the inner diameter of the hole and the pickup antenna is disposed inside the insertion portion; and

FIG. 7 is a vertical cross-sectional view of the vicinity of the hole in an example where the outer diameter of the insertion portion is smaller than the inner diameter of the hole and the electromagnetic wave propagating member is disposed inside the insertion portion.

### DETAILED DESCRIPTION OF THE INVENTION

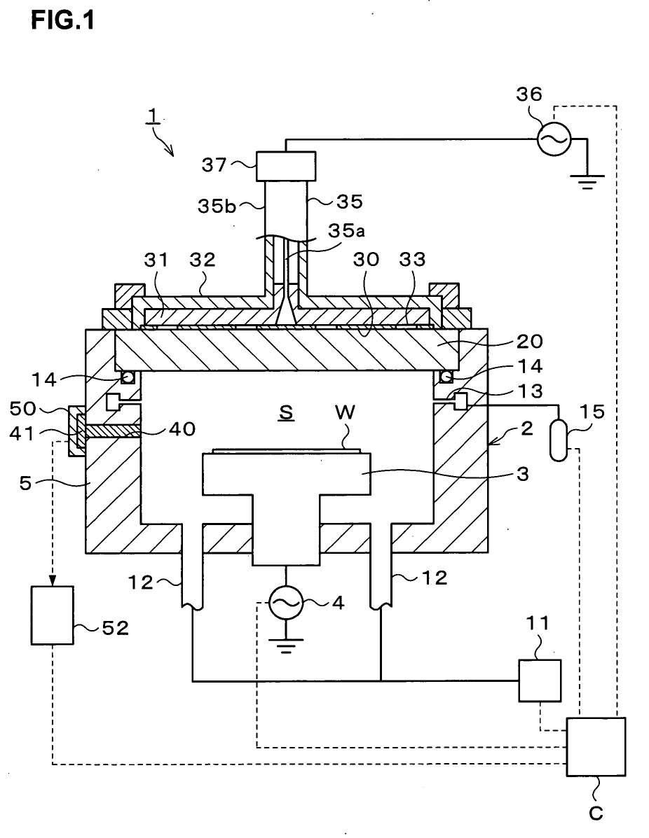

Hereinafter, an embodiment of the present invention will be described. FIG. 1 shows a vertical cross section of a plasma processing unit 1 according to this embodiment, and this plasma processing unit 1 includes a process vessel 2 made of, for example, aluminum, and formed in a bottomed cylindrical shape with an upper opening. The process vessel 2 is grounded. This process vessel 2 has in a bottom portion thereof a susceptor 3 for placing a substrate, for example, a semiconductor wafer (hereinafter, referred to as a wafer) W. The susceptor 3 is made of, for example, metal such as aluminum and is supplied with a bias high-frequency power from an AC power source 4 provided outside the process vessel 2. The susceptor 3 may be made of ceramics such as AlN, SiC, or the like. Further, the susceptor 3 may have a built-in heater capable of heating the substrate on the susceptor 3.

The process vessel 2 has in its bottom portion an exhaust pipe 12 through which an atmosphere inside the process vessel 2 is exhausted by an exhaust device 11 such as a vacuum pump. A gas introducing part 13 such as a gas nozzle for supplying process gas from a process gas supply source 15 is further provided on a sidewall of the process vessel 2.

A transmissive window 20 made of, for example, a quartz material is provided on the upper opening of the process vessel 2 via a seal member 14 such as an O-ring for ensuring airtightness. Other dielectric material, for example, ceramics such as AlN, sapphire, or the like may be used instead of the quartz material. Owing to this transmissive window 20, a process space S is formed in the process vessel 2. The transmissive window 20 has a circular plane section.

On the transmissive window 20, a planar antenna member, for example, a slot antenna 30 in a disk shape is provided. Further, on an upper face of this slot antenna 30, a retardation plate 31 is disposed, and a conductive cover 32 covering the retardation plate 31 is provided. The slot antenna 30 is constituted of a thin disk made of a conductive material, for example, copper plated or coated with Ag, Au, or the like, and has a large number of slits 33 arranged, for example, spirally or concentrically.

A coaxial waveguide 35 is connected to the cover 32, and this coaxial waveguide 35 is constituted of an inner conductor 35a and an outer pipe 35b. The inner conductor 35a is connected to the slot antenna 30. A slot antenna 30 side of the inner conductor 35a has a conical shape for efficient propagation of the microwave to the slot antenna 30. The coaxial waveguide 35 guides a microwave of, for example, 2.45 GHz generated in a microwave supply device 36 so that the microwave propagates to the transmissive window 20 through a load matching device 37, the coaxial waveguide 35, the retardation plate 31, and the slot antenna 30. Energy thereof forms an electric field on a lower face of the transmissive window 20 to plasmatize the process gas supplied into the process vessel 2 through the gas introducing part 13, so that predetermined processing, for example, reform processing of the substrate such as film deposition processing, etching processing, or the like is applied to the wafer W on the susceptor 3.

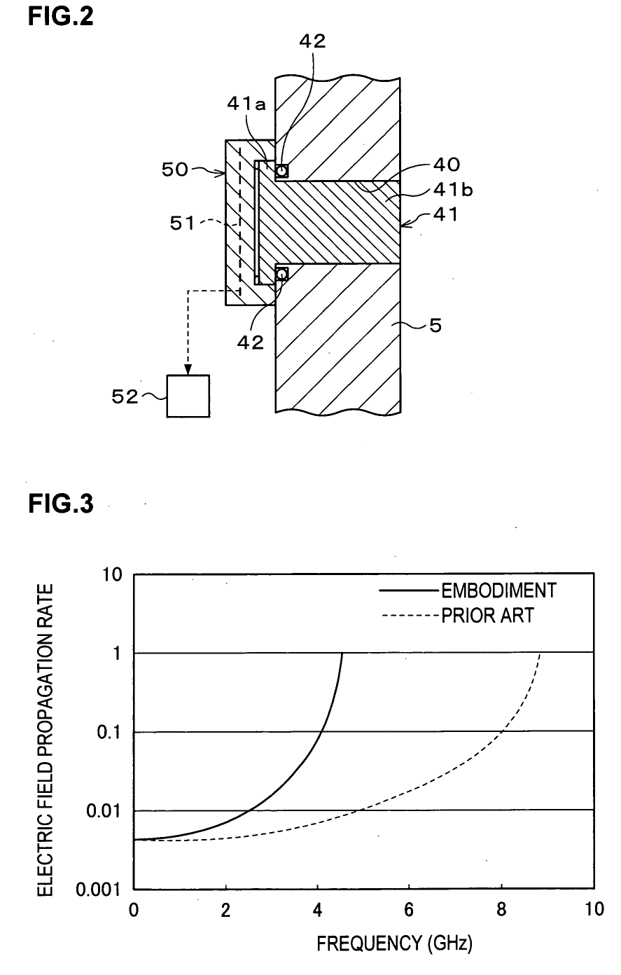

In an upper portion of the sidewall 5 of the process vessel 2, a hole 40 passing through the sidewall 5 is formed. As shown also in FIG. 2, a window member 41 airtightly covering an outer side of the hole 40 is provided on the outer side of the hole 40 via a seal member 42 such as an O-ring. The window member 41 is composed of a lock portion 41a locked at an outer peripheral portion of the hole 40 and an insertion portion 41b inserted airtightly in the hole 40. As a material of the window member 41, a dielectric, for example, quartz material is used. The insertion portion 41b fills the inside of the hole 40.

A detector 50 is disposed on an outer side of the window member 41. The detector 50 has a built-in pickup antenna 51 for picking up the electromagnetic wave.

As a material of the pickup antenna 51, conductive metal, for example, copper, platinum, gold, or silver is used. Alternatively, a member made of Al, SUS, ceramics, resin, or the like coated with one of the above materials may be used.

A frequency signal received by the pickup antenna 51 is outputted to a signal processor 52 installed outside the process vessel 2, and the signal processor 52 processes the frequency signal to detect whether or not abnormal discharge or the like exists.

Incidentally, the pickup antenna 51 may be disposed in the window member 41 as shown in the drawing.

Next, a control system of the plasma processing unit 1 will be described. The aforesaid AC power source 4, exhaust device 11, process gas supply source 15, microwave supply device 36, and signal processor 52 are all controlled by a controller C. With this, it is possible to, for example, set the pressure inside the process vessel 2 at a predetermined pressure value, and when abnormal discharge is detected by the signal processor 42, the supply of the process gas from the process gas supply source 15 and the supply of the microwave from the microwave supply device 36 are automatically stopped.

The plasma processing unit 1 according to this embodiment is configured as described above, and for plasma processing, the wafer W is placed on the susceptor 3 in the process vessel 2, and the atmosphere therein is exhausted through the exhaust pipe 12 while predetermined process gas is supplied into the process vessel 2 from the gas introducing part 13, so that the inside of the process space S is set at a predetermined pressure.

Then, the AC power source 4 applies the bias high-frequency power to the wafer W, the microwave supply device 36 generates a microwave, and the microwave is introduced into the process vessel 2 through the transmissive window 20 to generate an electric field under the transmissive window 20, so that the process gas in the process space S is plasmatized. Depending on the selected kind or the like of the process gas, predetermined plasma processing among various kinds of plasma processing, for example, oxidation processing, nitridation processing, oxynitridation processing, etching processing, ashing processing, film deposition processing, and the like can be applied to the wafer W.

In the plasma processing unit 1 according to this embodiment as described above, the inside of the hole 40 is filled with the insertion portion 41b of the window member 41 made of the dielectric, resulting in an improved propagation rate of the electromagnetic wave, which is generated due to abnormal plasma such as abnormal discharge, to the pickup antenna 51, compared with a propagation rate in a prior art where the inside of the hole is left hollow. Consequently, the pickup antenna 51 can have an improved sensitivity when the detector 50 detects via the hole 40 abnormality in plasma such as abnormal discharge generated in the process vessel 2. This can realize higher accuracy than in the prior art in detecting abnormal discharge and an abnormal plasma condition inside the process vessel 2. Moreover, this can be realized without any increase in size of the hole or without any reduction in thickness of the sidewall 5 of the process vessel 2. Therefore, the present invention is applicable to existing plasma processing units of this kind.

Further, the detector 50 may be provided at any position, not limited to the sidewall 5, of the process vessel 2 such as a bottom portion, an upper portion, or the susceptor portion of the process vessel 2 as long as the electromagnetic wave can be detected.

The present inventors studied effects of the present invention based on actual calculation and the results shown in the graph in FIG. 3 were obtained. This graph shows the correlation between frequency and electric field propagation rate to the pickup antenna 51 when the diameter of the hole 40 is 10 mm and the thickness of the sidewall 5 (the length of the hole 40) is 30 mm. As a material of the window member 41, a quartz material (with relative dielectric constant of 3.75) was used and the mode at the time of the measurement was the TE₁₁ mode.

As a result, the cutoff frequency was about 4.2 GHz in this embodiment while that in the prior art (with a hole 40 left hollow) was about 8.8 GHz, which led to the findings that a low cutoff frequency about half of that in the prior art or lower can be attained. Further, it is seen that as a whole, this embodiment achieves an improved propagation rate for the same frequency. Therefore, the detection of lower frequency than in the prior art can be achieved and sensitivity is improved, so that higher accuracy than in the prior art is attained in detecting abnormal discharge and an abnormal plasma condition in the process vessel 2.

In the embodiment described above, the quartz material is used as the material of the window member 41, but the material is not of course limited to this, and the window member 41 may be made of other dielectric, for example, alumina (with relative dielectric constant of 9.9), AlN, Si₃N₄, fluorine resin, or other resin. A material higher in dielectric constant can achieve a higher propagation rate. Further, one of these materials coated with Y₂O₃ superior in plasma resistance may be used.

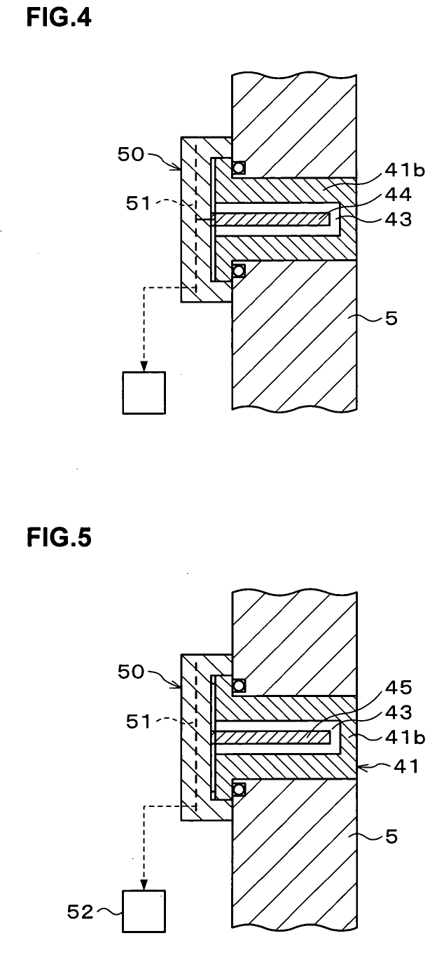

Further, the embodiment described above is simply structured such that the inside of the hole 40 is filled with the insertion portion 41b of the window member 41 made of the dielectric, but for higher propagation rate, an example shown in, for example, FIG. 4 may be adopted. In the example in FIG. 4, in addition to the structure shown in FIG. 2, a hollow portion 43 is further formed inside the insertion portion 41b of the window member 41 and another pickup antenna 44 electrically connected to the pickup antenna 51 is disposed in the hollow portion 43.

According to such an example, the electromagnetic wave generated in the process vessel 2 can be received at a position closer to the process space S in the process vessel 2, resulting in further improvement in propagation rate. Incidentally, in the example in FIG. 4, the pickup antenna 44 is provided separately from the pickup antenna 51 provided in the detector 50. However, such a structure may be adopted that the pickup antenna 51 in the detector 50 is not provided, and only the pickup antenna 44 disposed in the insertion portion 41b is provided so that the frequency signal received by the pickup antenna 44 is outputted to the signal processor 52. In short, only the pickup antenna 44 may be provided in place of the pickup antenna 51.

Further, the example shown in FIG. 4 is consequently a structure such that the pickup antenna having a receiving function is disposed in the insertion portion 41b, but an electromagnetic wave propagating member 45 that is independent of and not electrically connected to the pickup antenna 51 in the detector 50 may be disposed in the hollow portion 43, as shown in FIG. 5. As the electromagnetic wave propagating member 45, for example, a conductive wire rod or bar is usable.

When the electromagnetic wave propagating member 45 is thus provided, the attenuation of the electromagnetic wave can be inhibited owing to the electromagnetic wave propagating member 45, resulting in an improved propagation rate to the pickup antenna 51 in the detector 50 and an improved sensitivity thereof.

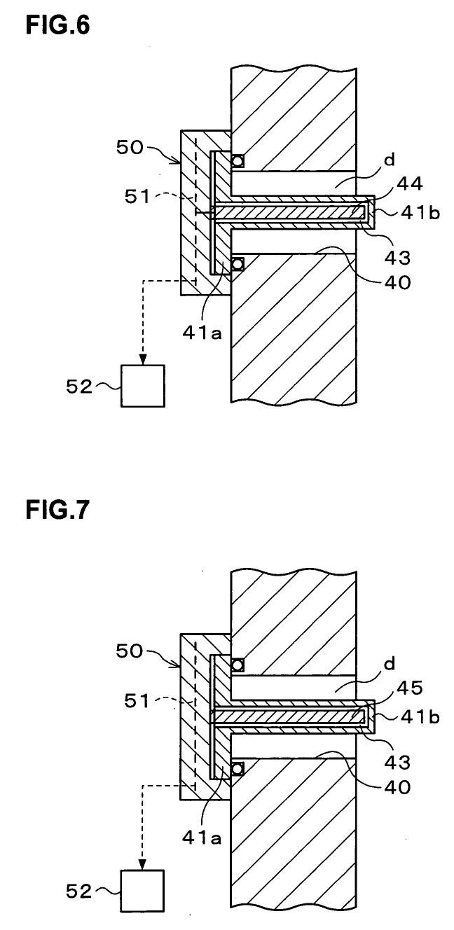

Further, in the examples in FIG. 4 and FIG. 5, the insertion portion 41b of the window member 41 has size and shape so as to fill the inside of the hole 40, but the outer diameter of the insertion portion 41b may be reduced so that a gap “d” is formed between an outer peripheral face of the insertion portion 41b and an inner peripheral face of the hole 40, as shown in FIG. 6. The insertion portion 41b in this case constitutes a covering member in the term of the present invention. The dielectric filling the inside of the hole 40 or the dielectric constituting the covering member described above is preferably made of the same material as that of the window member 41. This is because reflection is caused on an interface of members different in dielectric constant when an electromagnetic wave passes through the interface.

FIG. 6 shows an example where the pickup antenna 44 is disposed in the hollow portion 43 of the insertion portion 41b. Incidentally, in the example in FIG. 6, only the pickup antenna 44 may be provided instead of providing the pickup antenna 51. FIG. 7 shows an example where the electromagnetic wave propagating member 45 is disposed in the hollow portion 43 of the insertion portion 41b.

In the respective examples shown in FIG. 4 and FIG. 5, the pickup antenna 44 receives the electromagnetic wave and the electromagnetic wave propagating member 45 inhibits the attenuation of the electromagnetic wave, and thus, the entire hole 40 does not serve as a propagation route. Therefore, even the existence of the gap “d” as shown in FIG. 6 and FIG. 7 does not cause any problem in the detection.

Further, in the examples shown in FIG. 6 and FIG. 7, a tip portion of the insertion portion 41b protrudes from the hole 40 toward the inside of the process vessel 2, so that a tip of the pickup antenna 44 or the electromagnetic wave propagating member 45 is positioned still closer to the process space S. This allows the detection at a position still closer to the process space S than in the examples in FIG. 4 and FIG. 5, resulting in a still higher propagation rate, which enables highly accurate detection of abnormal discharge and the like.

As described above, the present invention is intended for efficient propagation of the electromagnetic wave, which is generated due to abnormal discharge, to the pickup antenna, and by utilizing this, it is also possible to detect the end of processing itself in various kinds of plasma processing, for example, plasma oxidation processing, plasma nitridation processing, plasma etching processing and plasma CVD processing.

For example, as for plasma etching processing, when an electromagnetic wave based on some etchant is constantly detected by the detector 50 and the detection result is monitored, the electromagnetic wave detected when the etchant contributes to etching is different from that detected when the etchant does not contribute to the etching. In other words, the electromagnetic wave detected before the etching processing presents a change when detected during the etching processing. Therefore, when the etching is finished, the detected electromagnetic wave returns to the electromagnetic wave detected before the etching processing. By utilizing this, it is possible to detect an instant at which the etching is finished, that is, a so-called end point.

As for plasma CVD processing, an electromagnetic wave when a film has a predetermined thickness is detected as a reference value in advance, and the electromagnetic wave is constantly detected by the detector 50 all through the CVD processing and the detection result is monitored. When a detected value reaches the reference detection value, it can be confirmed that the thickness has reached the predetermined value. That is, it can be detected that desired CVD processing is finished.

Examples of plasma etching processing and plasma CVD processing using the aforesaid plasma processing unit 1 will be described below.

Examples of plasma etching processing are as follows.

(1) W (Tungsten) Etching

Temperature of a wafer W: room temperature (23° C.) or lower
Power: 1000 W to 5000 W
Process pressure: 0.133 Pato 133 Pa
Process gas: Cl₂/N₂/O₂=150/150/20 sccm
   or Ar/Cl₂/N₂/O₂=200/100/75/5 sccm
      (2) Polysilicon Etching
Temperature of a wafer W: room temperature (23° C.) or lower
Power: 1000 W to 5000 W
Process pressure: 0.133 Pa to 133 Pa
Process gas: HBr=300 sccm
   or Ar/HBr/O₂=1200/400/100 sccm
   SF6 may be used.

Examples of plasma CVD processing are as follows.

(1) A Low-k Film (CF Film)

Temperature of a wafer W: room temperature (23° C.) or lower
Power: 1000 W to 5000 W
Process pressure: 1.33 Pa to 133 Pa
Process gas: Ar/C₅F₈=300/300 sccm

For example, in each process of the etching processing and the CVD processing as described above, a so-called end point of each processing can be detected by observing the electromagnetic wave.

The embodiment described above, which is constituted as the plasma processing unit utilizing the microwave, exhibits a high effect especially when being applied to a plasma processing unit utilizing a high-frequency plasma source. However, the present invention is not of course limited to this, and is applicable to various kinds of plasma processing units such as a so-called parallel plate (capacitive type) plasma processing unit, an ECR unit, an ICP-plane reflected wave plasma processing unit, and an ICP unit.

1. A plasma processing unit applying plasma processing to a substrate in a process vessel, comprising:
a dielectric at least partly facing a space in the process vessel;
a detector having a pickup antenna that receives, via said dielectric, an electromagnetic wave generated due to abnormal plasma in the process vessel.

2. The plasma processing unit as set forth in claim 1, further comprising:
a hole passing through a wall of the process vessel; and
a window member airtightly covering an outer side of said hole,
wherein at least an inside of said hole is filled with said dielectric.

3. The plasma processing unit as set forth in claim 2,
wherein said window member is made of a dielectric, and
wherein said window member has a lock portion locked at said hole outside the process vessel and an insertion portion inserted in said hole to fill the inside of said hole.

4. The plasma processing unit as set forth in claim 1,
wherein said pickup antenna is disposed in said dielectric.

5. The plasma processing unit as set forth in claim 1, further comprising
another pickup antenna disposed in said dielectric and electrically connected to said pickup antenna of said detector.

6. The plasma processing unit as set forth in claim 1, further comprising
an electromagnetic wave propagating member disposed in said dielectric and being independent of said pickup antenna of said detector.

7. A plasma processing unit applying plasma processing to a substrate in a process vessel, comprising:
a hole passing through a wall of the process vessel;
a window member airtightly covering an outer side of said hole; and
a detector having a pickup antenna that receives, via said hole, an electromagnetic wave generated due to abnormal plasma,
wherein said pickup antenna is disposed in said hole, being covered with a covering member made of a dielectric, and
wherein a gap exists between an outer peripheral face of the covering member and an inner peripheral face of said hole.

8. A plasma processing unit applying plasma processing to a substrate in a process vessel, comprising:
a hole passing through a wall of the process vessel;
a window member airtightly covering an outer side of said hole;
a detector having a pickup antenna that receives, via said hole, an electromagnetic wave generated due to abnormal plasma; and
an electromagnetic wave propagating member disposed in said hole, said electromagnetic wave propagating member being independent of the pickup antenna of said detector and being covered with a covering member made of a dielectric,
wherein a gap exists between an outer peripheral face of the covering member and an inner peripheral face of said hole.

9. The plasma processing unit as set forth in claim 7,
wherein a tip portion of the covering member protrudes from said hole toward an inside of the process vessel.

10. The plasma processing unit as set forth in claim 8,
wherein a tip portion of the covering member protrudes from said hole toward an inside of the process vessel.

11. The plasma processing unit as set forth in claim 2,
wherein said dielectric is made of a same material as a material of said window member.

12. The plasma processing unit as set forth in claim 1,
wherein the plasma processing is plasma processing utilizing a microwave for plasma generation.

13. The plasma processing unit as set forth in claim 1,
wherein said dielectric has a relative dielectric constant of 3.7 or higher.

14. The plasma processing unit as set forth in claim 1, further comprising
a controller controlling the plasma processing unit based on a result of detection by said detector.
